(19) United States
(12) Patent Application Publication
(10) Pub. No.: US 2026/0015716 A1
(43) Pub. Date: Jan. 15, 2026

(54) METHODS FOR SELECTIVELY DEPOSITING AN AMORPHOUS SILICON FILM ON A SUBSTRATE

(71) Applicant: ASM IP Holding B.V., Almere (NL)

(72) Inventor: Timothee Blanquart, Oud-Heverlee (BE)

(21) Appl. No.: 19/337,214

(22) Filed: Sep. 23, 2025

Related U.S. Application Data
(63) Continuation of application No. 18/100,637, filed on Jan. 24, 2023, now Pat. No. 12,448,682.
Application No. 18/100,637 is a continuation of application No. 16/673,860, filed on Nov. 4, 2019, now Pat. No. 11,572,620.
(60) Provisional application No. 62/756,368, filed on Nov. 6, 2018.

(51) Int. Cl. C23C 16/24; C23C 16/02; C23C 16/455

(52) U.S. Cl. CPC C23C 16/24; C23C 16/0209; C23C 16/45536

(57) ABSTRACT

A method for selectively depositing an amorphous silicon film on a substrate comprising a metallic nitride surface and a metallic oxide surface is disclosed. The method may include; providing a substrate within a reaction chamber, heating the substrate to a deposition temperature, contacting the substrate with silicon iodide precursor, and selectively depositing the amorphous silicon film on the metallic nitride surface relative to the metallic oxide surface. Semiconductor device structures including an amorphous silicon film deposited by selective deposition methods are also disclosed.

### CROSS-REFERENCE TO RELATED APPLICATION

This application is a continuation of, and claims priority to, U.S. patent application Ser. No. 18/100,637 filed Jan. 24, 2023 titled METHODS FOR SELECTIVELY DEPOSITING AN AMORPHOUS SILICON FILM ON A SUBSTRATE; which is a continuation of, and claims priority to, U.S. patent application Ser. No. 16/673,860, now U.S. Pat. No. 11,572,620, issued Nov. 4, 2019 titled METHODS FOR SELECTIVELY DEPOSITING AN AMORPHOUS SILICON FILM ON A SUBSTRATE; which claims the benefit of U.S. Provisional Patent Application No. 62/756,368 filed Nov. 6, 2018, the disclosures of which are incorporated herein in their entirety by reference.

### FIELD OF INVENTION

The present disclosure generally relates to methods for selectively depositing an amorphous silicon film on a substrate and particular selectively depositing an amorphous silicon film on a metallic nitride surface relative to a metallic oxide surface. Semiconductor device structures comprising a selective amorphous silicon film are also disclosed.

### BACKGROUND OF THE DISCLOSURE

In some applications it may be desirable to deposit an amorphous silicon film only on certain areas of a substrate. Typically, such discriminating results are achieved by depositing a continuous amorphous silicon film and subsequently patterning the amorphous silicon film using lithography and etch steps. Such lithography and etch processes may be time consuming and expensive, and do not offer the precision required for many applications. A possible solution is the use of selective deposition processes, whereby a film of material may be deposited only in the desired areas thereby eliminating the need for subsequent patterning steps. For example, selective deposition processes may take a number of forms, including, but not limited to, selective dielectric deposition on dielectric surfaces (DoD), selective dielectric on metallic surfaces (DOM), selective metal deposition on dielectric surfaces, and selective metal deposition on metallic surfaces (MoM).

Selective amorphous silicon deposition is of interest for providing methods for depositing amorphous silicon films without the need for complex patterning and etch steps. A common method for producing a substrate including selective amorphous silicon films may comprise a blanket deposition of the amorphous silicon film over the entire surface of the substrate, covering the amorphous silicon films with a patterned etch mask utilizing photolithography processes, and subsequently exposing the substrate to an etchant to remove the exposed regions of the amorphous silicon film not covered by the etch mask. However, such processes for the formation of patterned amorphous silicon films are complex, time consuming, cost prohibitive, and such processes only become more complex as device feature size decreases at advanced technology nodes.

Accordingly, methods are desired for selectively depositing an amorphous silicon film and particularly methods for selectively deposited an amorphous silicon film on a metallic nitride surface relative to a metallic oxide surface.

### SUMMARY OF THE DISCLOSURE

In accordance with at least one embodiment of the disclosure, a method for selectively depositing an amorphous silicon film on a substrate is disclosed. The method may comprise: providing a substrate within a reaction chamber; heating the substrate to a deposition temperature; contacting the substrate with silicon iodide precursor; and selectively depositing the amorphous silicon film on the metallic nitride surface relative to the metallic oxide surface.

In addition, semiconductor device structures including an amorphous silicon film deposited by selective deposition methods may be disclosed.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawing, in which:

FIG. 1 illustrates a process flow diagram illustrating an exemplary selective amorphous silicon deposition method in accordance with embodiments of the disclosure;

FIG. 2 illustrates a graph demonstrating the deposition thickness of various amorphous silicon films in relation to the deposition time for a number of different substrate surfaces according to the embodiments of the disclosure;

FIG. 3 illustrates a graph demonstrating the mass gain on a number of different substrate surfaces subsequent to a selective amorphous silicon deposition according to the embodiments of the disclosure;

FIG. 4A illustrates a scanning transmission electron microscope (STEM) image of a semiconductor device structure including a native oxide surface subsequent to a selective amorphous silicon deposition process according to the embodiments of the disclosure;

FIG. 4B illustrates a scanning transmission electron microscope (STEM) image of a semiconductor device structure including a silicon nitride surface subsequent to a selective amorphous silicon deposition process according to the embodiments of the disclosure;

FIG. 5A illustrates a cross sectional schematic diagram of a semiconductor device structure comprising a high aspect ratio feature and film deposited by a topographically selective deposition method; and

FIG. 5B illustrates a cross sectional schematic diagram of a semiconductor device structure comprising a high aspect ratio feature, a film deposited by a topographically selective deposition methods, and a selective amorphous silicon film deposited according to the embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials that may be used, or upon which, a device, a circuit, or a film may be formed.

As used herein, the term “chemical vapor deposition” may refer to any process wherein a substrate is exposed to one or more volatile precursors, which react and/or decompose on a substrate surface to produce a desired deposition.

As used herein, the term “amorphous silicon film” may refer to a silicon film that exhibits substantially no long range ordering of the crystalline structure that would normally be a characteristic of a crystalline film.

As used herein, the term “silicon iodide precursor” may refer to a precursor which comprises a silicon component and an iodide component.

As used herein, the term “metallic nitride surface” may refer to metal nitride surface, such as, but not limited to, transition metal nitride surfaces, as well as to metalloid nitride surfaces, such as, but not limited, a silicon nitride surface.

As used herein, the term “metallic oxide surface” may refer to metal oxide surface, such as, but not limited to, transition metal oxide surfaces, as well as to metalloid oxide surfaces, such as, but not limited, a silicon oxide surface.

As used herein, the term “selectively depositing” may refer to depositing a greater amount of material on a first surface relative to a second surface. In addition, the “selectivity” of a selective deposition process may be expressed as the ratio of material formed on the first surface relative to the amount of material formed on the first and second surfaces combined. For example, if a selective deposition processes deposits 10 nanometers of material on a first surface and 1 nanometer of material on a second surface, the selective deposition process will be considered to have 90% selectivity.

As used herein, the term “film” and “thin film” may refer to any continuous or non-continuous structures and material deposited by the methods disclosed herein. For example, “film” and “thin film” could include 2D materials, nanolaminates, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

The embodiments of the disclosure may include methods for selectively depositing an amorphous silicon film on a substrate and particularly methods for selectively depositing an amorphous silicon film on a metallic nitride surface relative to a metallic oxide surface, in other words, more amorphous silicon may be deposited on a metallic nitride surface relative to the amount of amorphous silicon deposited on a metallic oxide surface.

In some embodiments of the disclosure, the selective amorphous silicon films may be utilized as self-aligned hardmask materials for patterning applications. As a further example, the selective amorphous silicon films may be utilized for formation of dummy gate structures upon a silicon nitride seed layer wherein the selective amorphous silicon film is deposited from the bottom-up thereby filing a structure without void formation.

The embodiments of the disclosure therefore comprise methods for selectively depositing an amorphous silicon film on a substrate comprising a metallic nitride surface and a metallic oxide surface. The selective deposition methods may comprise: providing a substrate within a reaction chamber; heating the substrate to a deposition temperature, contacting the substrate with a silicon iodide precursor; and selectively depositing the amorphous silicon film on the metallic nitride surface relative to the metallic oxide surface.

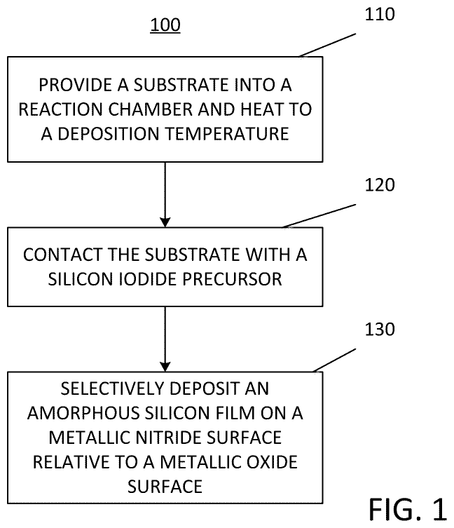

The methods of the disclosure may be understood with reference to FIG. 1 which illustrates an exemplary process flow demonstrating a non-limiting method for selectively depositing an amorphous silicon film. The method 100 of selectively depositing an amorphous silicon film may commence by means of a process block 110, which comprises providing a substrate into a reaction chamber and heating the substrate to a deposition temperature.

In some embodiments of the disclosure, the substrate may comprise a planar substrate or a patterned substrate. Patterned substrates may comprise substrates that may include semiconductor device structures formed into or onto a surface of the substrate; for example, the patterned substrates may comprise partially fabricated semiconductor device structures such as transistors and memory elements. A patterned substrate may comprise a non-planar surface which may comprise one or more fin structures extending up from the main surface of the substrate and/or one or more indentation extending into the surface of the substrate. The substrate may contain monocrystalline surfaces and/or one or more secondary surfaces that may comprise a non-monocrystalline surface, such as a polycrystalline surface and an amorphous surface. Monocrystalline surfaces may comprise, for example, one or more of: silicon (Si), silicon germanium (SiGe), germanium tin (GeSn), or germanium (Ge). Polycrystalline or amorphous surfaces may include dielectric materials, such as oxides, oxynitrides, or nitrides, including for example, silicon oxides and silicon nitrides.

In addition, the substrate may comprise one or more metallic nitride surfaces, such as, for example, transition metal nitrides surfaces and/or silicon nitride surfaces. In some embodiments, the metallic nitride surface may comprise at least one of a metal nitride surface or a metalloid surface. In some embodiments, the metal nitride surface may comprise at least one of titanium nitride, zirconium nitride, hafnium nitride, aluminum nitride, tantalum nitride, ruthenium nitride, tungsten nitride, molybdenum nitride, or cobalt nitride. In some embodiments, the metalloid nitride surface may comprise a silicon nitride. As used herein, the formula for the silicon nitride is generally referred to as SiN for convenience and simplicity. However, the skilled artisan will understand that the actual formula of the silicon nitride, representing the Si:N ratio in the film and excluding hydrogen or other impurities, can be represented as SiNₓ, where x varies from about 0.5 to about 2.0, as long as some Si—N bonds are formed. In some cases, x may vary from about 0.9 to about 1.7, from about 1.0 to about 1.5, or from about 1.2 to about 1.4. In some embodiments, silicon nitride is formed where Si has an oxidation state of +IV and the amount of nitride in the material may vary.

Further, the substrate may comprise one or more metallic oxide surfaces, such as, for example, transition metal oxide surfaces and/or silicon oxide surfaces. In some embodiments, the metallic oxide surface may comprise at least one of a metal oxide surface or a metalloid oxide surface. In some embodiments, the metal oxide surface may comprise at least one of titanium oxide, zirconium oxide, hafnium oxide, aluminum oxide, tantalum oxide, ruthenium oxide, tungsten oxide, molybdenum oxide, or cobalt oxide. In some embodiments, the metalloid oxide surface may comprise a silicon oxide, including silicon dioxide (SiO₂) and silicon suboxides (SiOₓ) wherein x<2.

The substrate may be disposed into a reaction chamber configured for selectively depositing an amorphous silicon films. In some embodiments, the selective amorphous silicon film may be deposited in a reaction chamber configured for a chemical vapor deposition (CVD), a soak process, an atomic layer deposition (ALD), a plasma-enhanced atomic layer deposition (PEALD), a plasma-enhanced chemical vapor deposition (PECVD), or a physical vapor deposition (PVD). In particular embodiments, the selective amorphous silicon film may be selectively deposited by a thermal chemical vapor deposition process and the reaction chamber may comprise a CVD reaction chamber, an ALD reaction chamber, a PEALD reaction chamber, or a PECVD reaction chamber. According to some embodiments, a showerhead reactor may be used. According to some embodiments, cross-flow, batch, minibatch, or spatial ALD reactors may be used.

In some embodiments of the disclosure, a batch reactor may be used. In some embodiments, a vertical batch reactor may be used. In other embodiments, a batch reactor comprises a minibatch reactor configured to accommodate 10 or fewer wafers, 8 or fewer wafers, 6 or fewer wafers, 4 or fewer wafers, or 2 or fewer wafers. In some embodiments in which a batch reactor is used, wafer-to-wafer non-uniformity is less than 3% (1 sigma), less than 2%, less than 1%, or even less than 0.5%.

The exemplary selective deposition processes as described herein may optionally be carried out in a reactor(s) or reaction chamber(s) connected to a cluster tool. In a cluster tool, because each reaction chamber is dedicated to one type of process, the temperature of the reaction chamber in each module can be kept constant, which improves the throughput compared to a reactor in which the substrate is heated up to the process temperature before each run. Additionally, in a cluster tool it is possible to reduce the time to pump the reaction chamber to the desired process pressure levels between substrates. In some embodiments of the disclosure, the exemplary processes disclosed herein may be performed in a cluster tool comprising multiple reaction chambers, wherein each individual reaction chamber may be utilized to expose the substrate to an individual precursor gas and the substrate may be transferred between different reaction chambers for exposure to multiple precursors gases, the transfer of the substrate being performed under a controlled ambient to prevent oxidation/contamination of the substrate.

In some embodiments, the exemplary process of selectively depositing an amorphous silicon film may be performed in a single stand-alone reactor which may be equipped with a load-lock. In that case, it is not necessary to cool down the reaction chamber between each run.

In some embodiments of the disclosure, the selective deposition methods of the current disclosure may be performed in a reaction chamber associated with PEALD apparatus and in such embodiments the gap between a substrate disposed in the reaction chamber and a showerhead for introducing gases into the reaction chamber may be between 3 millimeters and 100 millimeters.

With continued reference to FIG. 1, the process block 110 of exemplary method 100 may continue by heating the substrate to a desired deposition temperature within a reaction chamber. In some embodiments of the disclosure, the method 100 may comprise heating the substrate to a deposition temperature greater than the decomposition temperature of the silicon iodide precursor. For example, in some embodiments, the silicon precursor utilized to selectively deposit the amorphous silicon film may comprise a silicon iodide and the substrate may heated to a temperature above the decomposition of the silicon iodide precursor to thereby decompose the silicon iodide precursor to enable selective deposition of a substantially pure amorphous silicon film. Not to be bound by any theory or mechanism, but is proposed that the decomposition of the silicon iodide precursor produces iodine species which may passivate the metallic oxides surfaces of the substrate and thereby inhibit growth of the amorphous silicon films over the metallic oxide surface.

In some embodiments of the disclosure, the deposition temperature may be less than 900° C., or less than 800° C., or less than 700° C., or less than 600° C., or less than 550° C., or even less than 400° C. For example, in some embodiments, the deposition temperature may range between 400° C. and 900° C., or between 400° C. and 600° C., or between 400° C. and 550° C. In some embodiments, the deposition temperature may be greater than 400°, or greater than 500° C., or even greater than 600° C. In some embodiments, the deposition temperature may be greater than 600° C. and film deposited may comprise at least partially crystalline silicon.

In addition to controlling the temperature of the substrate, the pressure within the reaction chamber may also be regulated. For example, in some embodiments of the disclosure, the pressure within the reaction chamber may be less than 3000 Pascals, or less than 2000 Pascals, or even less than 1000 Pascals. In some embodiments, the pressure in the reaction chamber may be between 50 Pascals and 10000 Pascals, or between 1000 Pascals and 3000 Pascals.

The exemplary selective deposition method 100 of FIG. 1 may continue by means of a process block 120 comprising, contacting the substrate with a silicon iodide precursor.

In some embodiments, the silicon iodide precursor may be selected from the group comprising SiI₄, HSiI₃, H₂SiI₂, H₃SiI, Si₂I₆, HSi₂Is, H₂Si₂I₄, H₃Si₂I₃, H₄Si₂I₂, H₅Si₂I, or Si₃I₈. In some embodiments, the silicon iodide precursor may comprise at least one of SiI₂H₂, SiI₄, SiH₃, or SiI₃H. In some embodiments, the silicon iodide precursor may comprise SiI₂H₂. More detailed information regarding silicon iodide precursors may be found in U.S. Pat. No. 9,564,309, filed on Jan. 29, 2014, titled “SI PRECURSORS FOR DEPOSITION OF SIN AT LOW TEMPERATURES,” all of which is hereby incorporated by reference and made a part of this specification.

In some embodiment, the silicon iodide precursor may be stored in vessel and fed to the reaction chamber utilizing a dilution gas and a carrier gas. To enable sufficient partial pressure of the silicon iodide precursor, the vessel may include one or more heaters to heat the silicon iodide precursor and thereby control the partial pressure of the silicon iodide precursor. For example, the silicon iodide precursor may be heated to a temperature greater than 30° C., or greater than 50° C., or even greater than 70° C., or between a temperature range of approximately 35° C. and approximately 70° C. In some embodiments, the silicon iodide precursor may have a partial pressure between approximately 0.5 Pascals and 0.7 Pascals. In addition, in some embodiments, the dilution gas may comprise at least one of nitrogen, helium, or argon. Further, the carrier gas may comprise at least one of nitrogen, helium, or argon. In some embodiments, the silicon iodide precursor may be continuously flowed into the reaction whilst selectively depositing the amorphous silicon film.

In some embodiments, in addition to contacting the substrate with the silicon iodide precursor, a hydrogen gas may be concurrently flowed with the silicon iodide precursor into the reaction chamber. In some embodiments, the ratio of hydrogen gas to the dilution gas and the carrier gas may range between 1.25% and 5.15%.

The exemplary selective deposition method 100 may continue by means of a process block 130 comprising, selectively depositing the amorphous silicon film on the metallic nitride surface relative to the metallic oxide surface.

In some embodiments of the disclosure, the precursors utilized to selectively deposited the amorphous silicon film do not comprise plasma excited precursors, i.e., the amorphous silicon film may be deposited without plasma excitation of the precursors, in other words the amorphous silicon film may be deposited in a plasma free environment.

In some embodiments, the selectivity of the methods disclosed herein may be above about 80%, above about 90%, above about 95%, or even about 100%. In some embodiments, the selectivity of the deposition process is at least about 80%, which may be selective enough for some particular applications. In some cases the selectivity is at least about 50%, which may be selective enough for some particular applications.

In some embodiments of the disclosure, selectively depositing the amorphous silicon film further comprises, depositing greater than 10 nanometers of the amorphous silicon film on the metallic nitride surface with substantially no deposition of the amorphous silicon film on the metallic oxide surface. In some embodiments, selectively depositing the amorphous silicon film further comprises, depositing greater than 4 nanometers of the amorphous silicon film on the metallic nitride surface with substantially no deposition of the amorphous silicon film on the metallic oxide surface. In some embodiments, the selectivity of the deposition methods disclosed herein may increase with a decrease in deposition temperature. For example, in some embodiments, the selectivity may increase as the deposition temperature is reduced from approximately 550° C. to approximately 500° C.

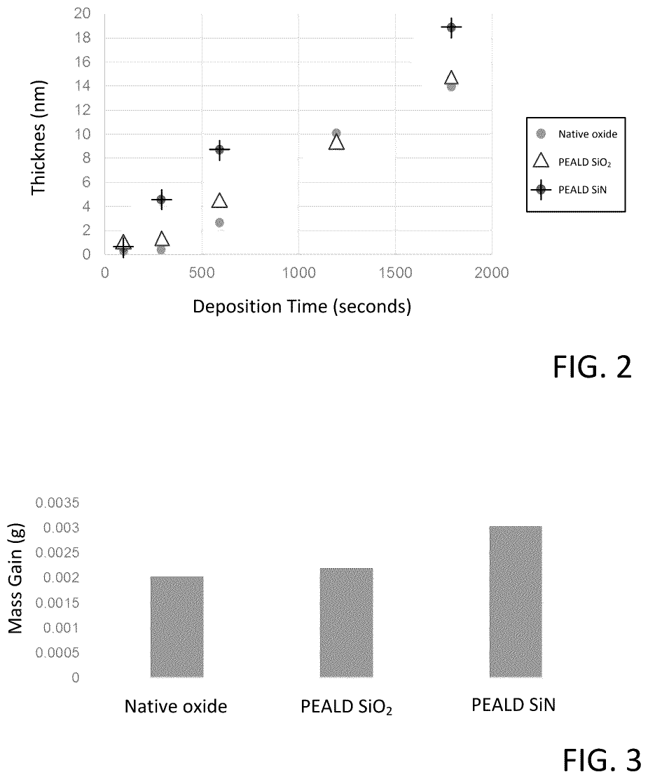

As a non-limiting example, FIG. 2 illustrates a graph demonstrating the deposition thickness of various amorphous silicon films in relation to the deposition time for a number of different substrate surfaces. It should be noted that all the amorphous silicon films making up the data in FIG. 2 were deposited according to the embodiments of the disclosure.

In more detail, the substrate surfaces utilized in this non-limiting example comprise a native silicon oxide (represented by the circular data markers), a silicon dioxide (SiO₂) deposited by a PEALD deposition process (represented by the triangular data markers), and a silicon nitride (SiN) deposited by a PEALD deposition process (represented by the cross data markers). Examination of FIG. 2 clearly demonstrates that the embodiments of the disclosure deposit a greater amount of the amorphous silicon film on the silicon nitride surface relative to the amount of the amorphous silicon film deposited over both the native oxide surface and the PEALD SiO2 surface.

The selectivity of the embodiments of the current disclosure may be further demonstrated with reference to FIG. 3 which illustrates a graph demonstrating the mass gain on a number of different substrate surfaces subsequent to a selective amorphous silicon film deposition according to the embodiments of the disclosure. In more detail, the amorphous silicon films were selectively deposited over a native oxide surface, a PEALD silicon dioxide surface (SiO2), and a PEALD silicon nitride surface (SiN). All the amorphous silicon films illustrated in FIG. 3 were deposited utilizing SiI₂H₂ as the silicon iodide precursor and the deposition time was 1800 seconds. Examination of FIG. 3 clearly demonstrates that the amorphous silicon film deposits to a greater amount, as indicated by the greater mass gain, over the silicon nitride surface in comparison to both the native oxide surface and the PEALD silicon oxide (SiO₂) surface.

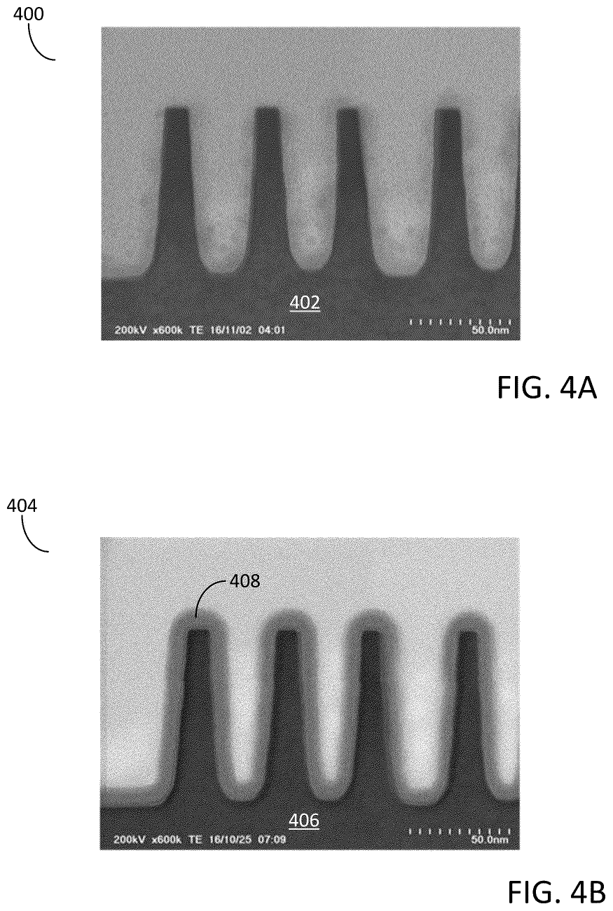

As further non-limiting examples of the embodiments of the disclosure, FIG. 4A illustrates a cross sectional scanning transmission electron microscopy (STEM) image of a semiconductor device structure 400 including a native oxide surface subsequent to a selective amorphous silicon deposition process and FIG. 4B illustrates a cross sectional scanning transmission electron microscopy (STEM) image of semiconductor device structure including a silicon nitride surface subsequent to a selective amorphous silicon deposition process.

Examination of the semiconductor device structure 400 (FIG. 4A) illustrates a silicon substrate 402 including high aspect ratio features covered by a native silicon oxide. It should be noted that the native silicon oxide cannot seen in the STEM image of FIG. 4A due to the extremely low thickness of the native silicon oxide film. The silicon substrate 402 was subjected to the selective amorphous silicon deposition processes of the current disclosure for a deposition period of 1800 seconds utilizing SiI₂H₂ as the silicon iodide precursor. Further examination of the STEM image of FIG. 4A clearly demonstrates that there is substantially no amorphous silicon film deposition over the native silicon oxide surface, as demonstrated by the lack of any film overlaying the silicon substrate 402.

Examination of the semiconductor device structure 404 (FIG. 4B) illustrates a silicon substrate 406 including high aspect ratio features covered by a silicon nitride seed layer. It should be noted that the silicon nitride seed cannot seen in the STEM image of FIG. 4A due to the extremely low thickness (approximately 3 Angstroms) of the silicon nitride seed layer. The silicon substrate 406, with SiN seed layer covering the surface, was subjected to the selective amorphous silicon deposition processes of the current disclosure for a deposition period of 1800 seconds utilizing SiI₂H₂ as the silicon iodide precursor. Further examination of the STEM image of FIG. 4B clearly demonstrates an amorphous silicon film 408 with a thickness of approximately 10 nanometers is disposed over the silicon nitride seed layer which is overlaying the silicon substrate 406.

In some embodiments, the selectively deposited amorphous silicon films deposited according to the embodiments of the current disclosure may achieve impurity levels or concentrations below about 3%, or below about 1%, or below about 0.5%, and or even below about 0.1%. In some embodiments the amorphous silicon films may have a total impurity level (excluding hydrogen) below about 5%, or below about 2%, or below about 1%, or even below about 0.2%. In some embodiments, the amorphous silicon films may have hydrogen levels below about 30%, or below about 20%, or below about 15%, or even below about 10%.

In some embodiments, the selectively deposited amorphous silicon films of the current disclosure do not comprise an appreciable amount of carbon. However, in some embodiments an amorphous silicon film comprising carbon is deposited. For example, in some embodiments a CLD process may be performed using a silicon iodide precursor comprising carbon and a thin amorphous silicon film comprising carbon may be deposited. In some embodiments, an amorphous silicon film comprising carbon may be deposited using a precursor comprising an alkyl group or other carbon-containing ligand.

In some embodiments of the disclosure, the selective amorphous silicon may exhibit step coverage and pattern loading effects of greater than about 50%, or greater than about 80%, or greater than about 90%, or even greater than about 95%. In some cases step coverage and pattern loading effects can be greater than about 98% and in some case about 100% (within the accuracy of the measurement tool or method). These values can be achieved in aspect ratios of more than 2, or more than 5, or more than 10, or even aspect ratios more than 25.

As used herein, “pattern loading effect” is used in accordance with its ordinary meaning in this field. While pattern loading effects may be seen with respect to impurity content, density, electrical properties and etch rate, unless indicated otherwise the term pattern loading effect when used herein refers to the variation in film thickness in an area of the substrate where structures are present. Thus, the pattern loading effect can be given as the film thickness in the sidewall or bottom of a feature inside a three-dimensional structure relative to the film thickness on the sidewall or bottom of the three-dimensional structure/feature facing the open field. As used herein, a 100% pattern loading effect (or a ratio of 1) would represent about a completely uniform film property throughout the substrate regardless of features, i.e., in other words there is no pattern loading effect (variance in a particular film property, such as thickness, in features vs. open field).

In some embodiments, the selective amorphous silicon films of the current disclosure may be deposited selectively over a metallic nitride surface at a deposition rate greater than 0.4 nm/min, or greater than 0.5 nm/min, or even greater than 0.6 nm/min.

In some embodiments of the disclosure, the selective amorphous silicon films are deposited to a thickness from about 0.1 nm to about 40 nm, or from about 1 nm to about 20 nm, or from about 1.5 nm to about 5 nm. These thicknesses can be achieved in feature sizes (width) below about 100 nm, or below about 50 nm, or below about 30 nm, or below about 20 nm, or even below about 15 nm. According to some embodiments, amorphous silicon films may be deposited on a three-dimensional structure and the thickness at a sidewall may be greater than approximately 10 nm.

In some embodiments of the disclosure, the selective amorphous silicon films of the current disclosure may be subjected to one or more post deposition processes. As a non-limiting example, the methods of the disclosure may further comprise contacting the amorphous silicon film with a plasma generated from an oxygen containing gas and converting at least a portion of the amorphous silicon nitride film to a silicon oxide film.

In some embodiments, the selective deposition of the amorphous silicon film and the post deposition process of contacting the amorphous silicon film with an oxygen plasma may be performed within the same reaction chamber, such as, a reaction chamber associated with a PEALD apparatus.

In some embodiments, the oxygen containing gas may comprise one or more of ozone (O₃), or molecular oxygen (O₂). In some embodiments, the plasma may comprise oxygen atoms, oxygen ions, oxygen radicals, and excited species of oxygen produced by the plasma excitation of the oxygen containing gas.

In some embodiments, the entire thickness of the amorphous silicon film may be converted to a silicon oxide by contacting the amorphous silicon film with any oxygen based plasma. In some embodiments, the selective amorphous silicon film may be converted to silicon dioxide (SiO₂), and/or one or more silicon suboxides (SiOₓ) wherein x<2.

The embodiments of the disclosure thereby provide methods for selectively forming a silicon oxide film on a metallic nitride surface relative to a metallic oxide surface. As a non-limiting example, the metallic nitride surface may comprise a silicon nitride (SiN) and the metallic oxide surface may comprise silicon dioxide (SiO₂) and the embodiments of the disclosure may selectively deposit an amorphous silicon film directly over the silicon nitride surface. Subsequent the amorphous silicon film may be fully converted to a silicon oxide film by contacting the amorphous silicon film with an oxygen based plasma thereby selectively forming a silicon oxide film over a silicon nitride surface relative to a silicon oxide surface.

The methods of the current disclosure may also comprise performing one or more selective deposition-etch cycles wherein a unit cycle comprises selectively depositing the amorphous silicon film and subsequent contacting the amorphous silicon film with an etchant to remove at least a portion of the amorphous silicon nitride film. In some embodiments, the etchant substantially removes the amorphous silicon nuclei disposed over the metallic oxide surface furthermore extending selectivity window. In some embodiments, the etchant may comprise a chlorine gas or a chlorine based plasma. In some embodiments, the selective amorphous deposition process and the subsequent etch process may be performed in the same reaction chamber, such as, a reaction chamber associated with a PEALD apparatus, for example.

As a non-limiting example, the embodiments of the disclosure may be utilized to selectively deposit greater than approximately 10 nm of an amorphous silicon film over the surface of substrate comprising a silicon nitride surface and a silicon oxide surface. The amorphous silicon film may be deposited to a greater amount over the silicon nitride surface relative to the amount of the amorphous silicon film deposited over the silicon oxide surface. However, in some embodiments, a certain amount of an amorphous silicon film may be deposited over the silicon oxide surface and the residual amorphous silicon film disposed over the silicon oxide film (due to less than 100% selectivity) may be removed by contacting the amorphous silicon film with an etchant thereby completely removing the amorphous silicon film disposed over the silicon oxide surface but only partially removing the amorphous silicon film disposed over the silicon nitride surface. The steps of selectively depositing the amorphous silicon film and subsequently removing residual amorphous silicon disposed over the silicon oxide surface may be repeated one or more times to enable the selective formation of thick amorphous silicon films over the silicon nitride surface of the substrate.

In some embodiments of the disclosure, the metallic nitride surface comprises a surface of a metallic nitride film deposited in the same reaction chamber as the amorphous silicon film. As a non-limiting example, the metallic nitride material may comprise a silicon nitride material deposited in a PEALD reaction chamber and the selective amorphous silicon film may be selectively deposited over the silicon nitride material surface in the same PEALD reaction chamber. More detailed information regarding amorphous silicon formation over a silicon nitride surface may be found in U.S. Publication No. 2018/0182613, filed on Dec. 15, 2017, titled “METHOD OF FORMING A STRUCTURE ON A SUBSTRATE,” all of which is hereby incorporated by reference and made a part of this specification.

In some embodiments of the disclosure, the metallic nitride surface comprises a metallic nitride film deposited by a topographically selective deposition process. In some embodiments, the metallic nitride film comprises a silicon nitride deposited by a topographically selective deposition process. More detailed information regarding topographically selective deposition processes may be found in U.S. Pat. No. 9,754,779, filed on Feb. 19, 2016, titled “METHOD OF FORMING A SILICON NITRIDE FILM SELECTIVELY ON SIDEWALSS OR FLAT SURFACES OF TRENCHES,” all of which is hereby incorporated by reference and made a part of this specification.

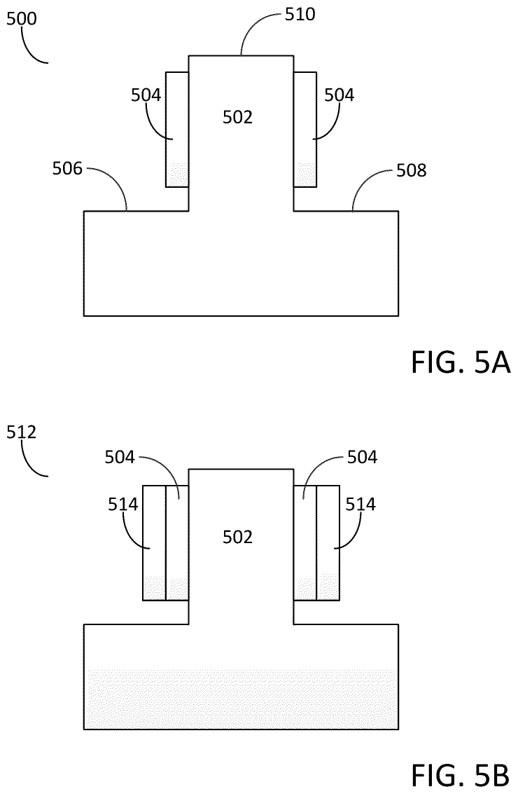

In more detail, FIG. 5A illustrates a cross section schematic diagram of a semiconductor structure 500 including a high aspect ratio feature 502 and a metallic nitride material 504 deposited by a topographically selective deposition process. As an alternative example, the metallic nitride material may be disposed only on lateral surfaces 506, 508, and 510. As a further example, the metallic nitride material may be disposed only on surfaces 506 and 508.

In some embodiments, a selective amorphous silicon film may be deposited utilizing the embodiments of the disclosure only over the surfaces of the metallic nitride material deposited by the topographically selective deposition process. For example, FIG. 5B illustrates a cross sectional schematic diagram of a semiconductor structure 512 including the high aspect ratio feature 502, a metallic nitride material 504 deposited by a topographically selective deposition process, and selective amorphous silicon film 514 disposed directly over the topographically selectively deposited metallic nitride material.

The embodiments of the disclosure also comprise semiconductor device structures comprising a selective amorphous silicon film deposited according to the embodiments of the disclosure.

The embodiments of the disclosure also comprise semiconductor deposition apparatus configured to perform the methods of the current disclosure.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for selectively depositing a silicon film on a substrate comprising a metallic nitride surface and a metallic oxide surface, the method comprising:
providing a substrate within a reaction chamber;
heating the substrate to a deposition temperature;
contacting the substrate with a silicon iodide precursor utilizing a dilution gas and a carrier gas;
using a thermal chemical vapor deposition process, contacting the substrate with hydrogen gas concurrently with contacting the substrate with the silicon iodide precursor; and
selectively depositing the silicon film on the metallic nitride surface relative to the metallic oxide surface.

2. The method of claim 1, wherein the metallic nitride surface comprises a transition metal nitride surface.

3. The method of claim 2, wherein the transition metal nitride surface comprises at least one of titanium nitride, zirconium nitride, hafnium nitride, aluminum nitride, tantalum nitride, ruthenium nitride, tungsten nitride, molybdenum nitride, or cobalt nitride.

4. The method of claim 2, wherein the transition metal nitride surface comprises at least one of titanium nitride, hafnium nitride, aluminum nitride, tantalum nitride, ruthenium nitride, tungsten nitride, and molybdenum nitride.

5. The method of claim 1, wherein the metal oxide surface comprises at least one of titanium oxide, zirconium oxide, hafnium oxide, aluminum oxide, tantalum oxide, ruthenium oxide, tungsten oxide, molybdenum oxide, or cobalt oxide.

6. The method of claim 1, wherein the metal oxide surface comprises at least one of titanium oxide, zirconium oxide, hafnium oxide, aluminum oxide, tantalum oxide, ruthenium oxide, tungsten oxide, or molybdenum oxide.

7. The method of claim 1, wherein the deposition temperature is greater than 400° C.

8. The method of claim 1, wherein the silicon iodide precursor comprises at least one of SiI₂H₂, SiI₄, SiIH₃, or SiI₃H.

9. The method of claim 1, wherein the selectivity is greater than 90%.

10. The method of claim 1, wherein selectively depositing the silicon film further comprises depositing greater than 4 nanometers of the silicon film on the metallic nitride surface with substantially no deposition of the silicon film on the metallic oxide surface.

11. The method of claim 1, wherein selectively depositing the silicon film further comprises depositing greater than 10 nanometers of the silicon film on the metallic nitride surface with substantially no deposition of the silicon film on the metallic oxide surface.

12. The method of claim 1, wherein the metallic nitride surface comprises a surface of a metallic nitride film deposited in the same reaction chamber as the silicon film.

13. The method of claim 1, wherein the silicon iodide precursor has a partial pressure between 0.5 Pascals and 0.7 Pascals.

14. The method of claim 1, further comprising regulating the pressure within the reaction chamber between 1000 Pascals and 3000 Pascals.

15. The method of claim 1, further comprising contacting the silicon film with a plasma generated from an oxygen containing gas and converting at least a portion of the silicon film to a silicon oxide film.

16. The method of claim 1, further comprising performing one or more selective deposition-etch cycles wherein a unit cycle comprises selectively depositing the silicon film and subsequent contacting the silicon film with an etchant to remove at least a portion of the silicon film.

17. The method of claim 1, wherein the metallic nitride film is deposited by a topographically selective deposition process.

18. The method of claim 1, wherein the silicon iodide precursor is continuously flowed into the reaction chamber whilst selectively depositing the silicon film.

19. The method of claim 1, wherein the silicon film is at least partially crystalline.

20. A structure comprising a silicon film formed according to the method of claim 1.
